(19) United States
(12) Patent Application Publication
(10) Pub. No.: US 2011/0048954 A1
(43) Pub. Date: Mar. 3, 2011

(54) ENHANCED SOLDERABILITY USING A SUBSTANTIALLY PURE NICKEL LAYER DEPOSITED BY PHYSICAL VAPOR DEPOSITION

(75) Inventor: BERNARD J. ROD, Potomac, MD (US)

(73) Assignee: U.S. Government as represented by the Secretary of the Army, Adelphi, MD (US)

(21) Appl. No.: 12/553,394

(22) Filed: Sep. 3, 2009

(51) Int. Cl. C23C 14/34; C25D 5/02

(52) U.S. Cl. 205/92; 205/192; 204/192.15

(57) ABSTRACT

A first preferred method for increasing the solderability of a substrate comprising: preparing the substrate for nickel plating by cleaning and removal of surface contaminants; plating a first nickel film of the desired thickness directly onto the substrate; preparing the nickel film comprising thoroughly cleaning the surface; depositing a substantially pure nickel film directly on the first nickel film using a suitable PVD technique; and applying solder to the substantially pure nickel film. Another preferred method for increasing the solderability of a substrate comprising plating a first nickel layer directly onto the substrate by using an electrolytic or electroless nickel plating process; depositing a substantially pure nickel film directly on the first nickel film using physical vapor deposition; and applying solder to the substantially pure nickel film.

### GOVERNMENT INTEREST

The invention described herein may be manufactured, used, and/or licensed by or for the United States Government.

### FIELD OF THE INVENTION

This invention relates generally to soldering, and more particularly to coatings which increase the solderability or effectiveness of a solder joint.

### BACKGROUND OF THE INVENTION

Current practice is to solder directly to the nickel plate used in electronics assemblies. However, the contamination in the nickel from the plating processes can prevent reliable solder connections from being made. Although some nickel plating processes, such as a low phosphorus process, can improve the solderability conditions, problems with reliability can still occur with high currents over a long period of time due to the contamination species in the nickel films. Other nickel soldering processes rely on more complicated techniques such as inter-layers and reflow operations to improve the solder to nickel bond. See for example Y. M. Chow, et al., “Feasibility and Reliability Study on the Electroless Nickel Bumping and Stencil Solder Printing for Low-cost Flip Chip Electronic Packaging,” 2000 IEEE International Symposium on Electronic Materials and Packaging, pages 79-85.

### SUMMARY OF THE INVENTION

A preferred embodiment of the present invention is a method to provide reliable solder connections to nickel plated electronics boards and parts, including quick turnaround prototype circuits and device evaluation circuits. This method relies on a high purity nickel layer deposited by a suitable physical vapor deposition (PVD) technique, such as e-beam evaporation, sputtering, etc., on an existing nickel plated nickel layer. The high purity layer (i.e. approximately at least 99.98% purity) eliminates solderability and reliability problems often associated with soldering directly to plated nickel films. The basic process steps flow for this method comprise: (1) preparing a substrate for nickel plating; (2) plating the nickel film to desired thickness using desired plating method; (3) preparing the nickel film for evaporation by thoroughly cleaning the film—the surface; may also be slightly roughened to insure good adhesion to deposited nickel film; and (4) depositing the substantially pure nickel film using a suitable PVD technique.

### BRIEF DESCRIPTION OF THE DRAWINGS

The present invention can best be understood when reading the following specification with reference to the accompanying drawings, which are incorporated in and form a part of the specification, illustrate alternate embodiments of the present invention, and together with the description, serve to explain the principles of the invention. In the drawings:

FIG. 1 is a flow chart of a preferred embodiment methodology of the present invention.

### DETAILED DESCRIPTION OF THE PREFERRED EMBODIMENTS

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

The terminology used herein is for the purpose of describing particular embodiments only and is not intended to limit the full scope of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The terminology “layer” as used in the following claims is not intended to be limiting; including as to size or dimension. The “layer” as used in the claims may be part of a composite device composed of various layers or the “layer” may be a part of a uniform material.

A preferred embodiment of the present invention is a method to provide reliable solder connections to nickel plated electronics boards and parts, especially for quick turnaround prototype circuits and device evaluation. This method relies on the deposition of a high purity nickel layer by a suitable physical vapor deposition (PVD) technique, such as e-beam evaporation, sputtering, etc., on an existing nickel plated nickel layer. The high purity layer, approximately 99.98% pure, eliminates solderability and reliability problems often associated with soldering directly to plated nickel films, which can contain contaminants or impurities.

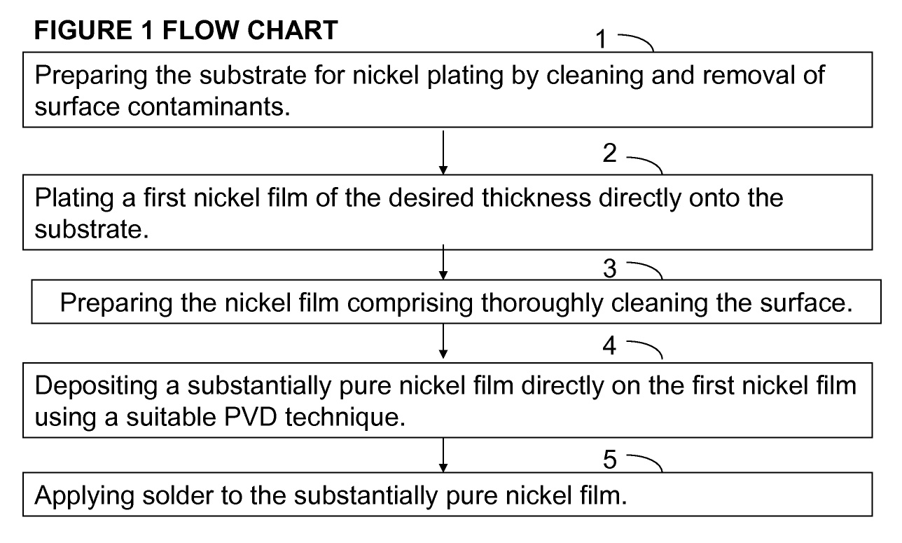

The basic process steps of a preferred embodiment methodology are shown in FIG. 1. In step 1, the substrate is first prepared for the nickel plating by cleaning or removal of surface impurities. In step 2, a nickel film is plated to the desired thickness using any one of a number of plating methods, such as electrolytic or electroless nickel plating processes. In step 3, the nickel film is prepared for evaporation by thoroughly cleaning the film and the surface may also be slightly roughened to ensure good adhesion to deposited nickel film. Techniques such as a brief sputter etch, ion-beam etch or mechanical abrasion may be employed to slightly roughen the surfaces to be coated. In step 4, an ultra pure nickel film is deposited on the existing nickel layer using a suitable PVD technique, such as, for example, electron beam (or e-beam) evaporation, sputtering, pulsed laser deposition, and ion assisted deposition. Step 5 comprises the application of the solder. The above steps are merely illustrative and are not limiting as to the scope of the invention. The invention may be practice using variants of the above steps without departing from the scope of the invention. For example, the step 3 may be eliminated when there is no need for cleaning of the first nickel layer. Steps 1 and 2 may be eliminated when the nickel plating is already in existence. Step 5 is not essential to the invention inasmuch as the solder may be applied at a subsequent place and/or time.

It should be emphasized that the above-described embodiment is merely a possible example of implementations of the invention. Although a preferred embodiment of the present invention has been described herein in detail to provide for complete and clear disclosure, it will be appreciated by those skilled in the art, which variations may be made thereto without departing from the spirit of the invention. Many variations and modifications may be made to the above-described embodiment. All such modifications and variations are intended to be included herein within the scope of the disclosure and protected by the following claims.

1. A method for increasing the solderability of a substrate comprising:
preparing the substrate for nickel plating by cleaning and removal of surface contaminants;
plating a first nickel film of the desired thickness directly onto the substrate;
preparing the nickel film comprising thoroughly cleaning the surface;
depositing a substantially pure nickel film directly on the first nickel film using physical vapor deposition; and
applying solder to the substantially pure nickel film.

2. The method of claim 1 wherein the step of preparing the nickel film further comprises roughening the surface using a brief sputter etch, ion-beam etch or mechanical abrasion.

3. The method of claim 1 wherein the step of depositing a substantially pure nickel film comprises using an electron beam evaporation technique.

4. The method of claim 1 wherein the step of depositing a substantially pure nickel film comprises using a sputtering technique.

5. The method of claim 1 wherein the step of depositing a substantially pure nickel film comprises using a pulsed laser deposition technique.

6. The method of claim 1 wherein the step of depositing a substantially pure nickel film comprises using an ion assisted deposition technique.

7. The method of claim 1 wherein the thickness of the substantially pure nickel film is in the range of approximately 1000 angstrom to several microns.

8. The method of claim 1 wherein the purity of the substantially pure nickel film is approximately at least 99.98% pure.

9. The method of claim 1 wherein the step of plating a first nickel film of the desired thickness directly onto the substrate comprises using an electrolytic or electroless nickel plating process.

10. A method for increasing the solderability of a substrate comprising:
plating a first nickel layer directly onto the substrate by using an electrolytic or electroless nickel plating process;
depositing a substantially pure nickel film directly on the first nickel film using physical vapor deposition; and
applying solder to the substantially pure nickel film.

11. The method of claim 1 further comprising a step of preparing the nickel layer comprising roughening the surface using a brief sputter etch, ion-beam etch or mechanical abrasion.

12. The method of claim 1 wherein the step of depositing a substantially pure nickel film comprises using an electron beam evaporation technique.

13. The method of claim 1 wherein the step of depositing a substantially pure nickel film comprises using a sputtering technique.

14. The method of claim 1 wherein the step of depositing a substantially pure nickel film comprises using a pulsed laser deposition technique.

15. The method of claim 1 wherein the step of depositing a substantially pure nickel film comprises using an ion assisted deposition technique.

16. The method of claim 1 wherein the thickness of the substantially pure nickel film is in the range of approximately 1000 angstrom to several microns.

17. The method of claim 1 wherein the purity of the substantially pure nickel film is at least 99.98% pure.
